(19) United States
(12) Patent Application Publication
(10) Pub. No.: US 2025/0015213 A1
(43) Pub. Date: Jan. 9, 2025

(54) FORMATION OF PHOTODIODE ABSORPTION REGION USING A SACRIFICIAL REGION

(71) Applicant: Cisco Technology, Inc., San Jose, CA (US)

(72) Inventors: Vipulkumar K. PATEL, Breinigsville, PA (US); Xunyuan ZHANG, Mechanicsburg, PA (US)

(21) Appl. No.: 18/346,558

(22) Filed: Jul. 3, 2023

(51) Int. Cl. H01L 31/0352; H01L 31/0232; H01L 31/105; H01L 31/18

(52) U.S. Cl. CPC H01L 31/035281; H01L 31/02327; H01L 31/105; H01L 31/1808

(57) ABSTRACT

The present disclosure relates to a photodiode and method of forming the photodiode. The photodiode includes a doped layer and an absorption region positioned on the doped layer. The absorption region includes a base region contacting the doped layer, a first facet region positioned on the base region, and a second facet region positioned on the first facet region. The first facet region includes (i) a first tapered surface and a second tapered surface extending from the base region and (ii) a first step region and a second step region extending laterally from the first tapered surface and the second tapered surface, respectively. The second facet region includes a third tapered surface extending from the first step region and a fourth tapered surface extending from the second step region.

### TECHNICAL FIELD

Embodiments presented in this disclosure generally relate to photodiodes. More specifically, embodiments disclosed herein relate to a process for forming an absorption region for a photodiode using a sacrificial region.

### BACKGROUND

Photodiodes convert optical signals into electrical signals. The photodiodes may include an absorption region through which optical signals pass. The optical signals separate electrical carriers in the absorption region, generating electrical signals.

### BRIEF DESCRIPTION OF THE DRAWINGS

So that the manner in which the above-recited features of the present disclosure can be understood in detail, a more particular description of the disclosure, briefly summarized above, may be had by reference to embodiments, some of which are illustrated in the appended drawings. It is to be noted, however, that the appended drawings illustrate typical embodiments and are therefore not to be considered limiting; other equally effective embodiments are contemplated.

FIG. 1 illustrates an example photodiode.

FIG. 2 illustrates an example portion of the photodiode of FIG. 1.

FIGS. 3A through 3F illustrate steps of an example process for forming the photodiode of FIG. 1.

FIGS. 4A and 4B illustrate steps of an example process for forming the photodiode of FIG. 1.

FIG. 5 illustrates a step of an example process for forming the photodiode of FIG. 1.

FIG. 6 is a flowchart of an example method of forming the photodiode of FIG. 1.

To facilitate understanding, identical reference numerals have been used, where possible, to designate identical elements that are common to the figures. It is contemplated that elements disclosed in one embodiment may be beneficially used in other embodiments without specific recitation.

### DESCRIPTION OF EXAMPLE EMBODIMENTS

### Overview

The present disclosure relates to a photodiode and method of forming the photodiode. According to an embodiment, a photodiode includes a doped layer and an absorption region positioned on the doped layer. The absorption region includes a base region contacting the doped layer, a first facet region positioned on the base region, and a second facet region positioned on the first facet region. The first facet region includes (i) a first tapered surface and a second tapered surface extending from the base region and (ii) a first step region and a second step region extending laterally from the first tapered surface and the second tapered surface, respectively. The second facet region includes a third tapered surface extending from the first step region and a fourth tapered surface extending from the second step region.

According to another embodiment, a method of forming a photodiode includes etching a first cavity in an oxide layer to expose a doped layer and forming a first absorption region on the doped layer. The method also includes filling the first cavity in the oxide layer and etching a second cavity in the oxide layer to expose the first absorption region. The method further includes removing the first absorption region to produce a third cavity and forming a second absorption region in the third cavity.

According to another embodiment, an absorption region of a photodiode includes a base region, a first facet region positioned on the base region, and a second facet region positioned on the first facet region. The first facet region includes (i) a first tapered surface and a second tapered surface extending from the base region and (ii) a first step region and a second step region extending laterally from the first tapered surface and the second tapered surface, respectively. The second facet region includes a third tapered surface extending from the first step region and a fourth tapered surface extending from the second step region.

### EXAMPLE EMBODIMENTS

Photodiodes are used in optical networks to convert optical signals into electrical signals. The speed of the photodiodes may be one of the key limitations to the speed of the optical networks. One way to increase the speed of the photodiodes is to reduce the size (e.g., width and thickness) of the photodiodes. Reducing the size of the photodiodes, however, may bring oppositely doped regions in the photodiodes (e.g., a p-doped silicon cap and an n-doped substrate region) too close to each other, which may result in junction breakdown and dark current spikes.

The present disclosure describes a photodiode and a process for forming the photodiode. Generally, the photodiode has an absorption region that creates increased physical separation between oppositely doped regions. The absorption region has a base region that is positioned within a cavity of a doped layer. A first facet region is positioned on the base region, and a second facet region is positioned on the first facet region. A silicon cap (e.g., p-doped silicon cap) is positioned on the first facet region and the second facet region.

In certain embodiments, the photodiode provides several technical advantages. For example, as a result of the shape of the absorption region, the absorption region creates additional physical separation between the silicon cap and a doped layer (e.g., an n-doped layer) in both lateral and vertical directions relative to existing photodiodes. Thus, the photodiode reduces the chances of junction breakdown and dark current spikes.

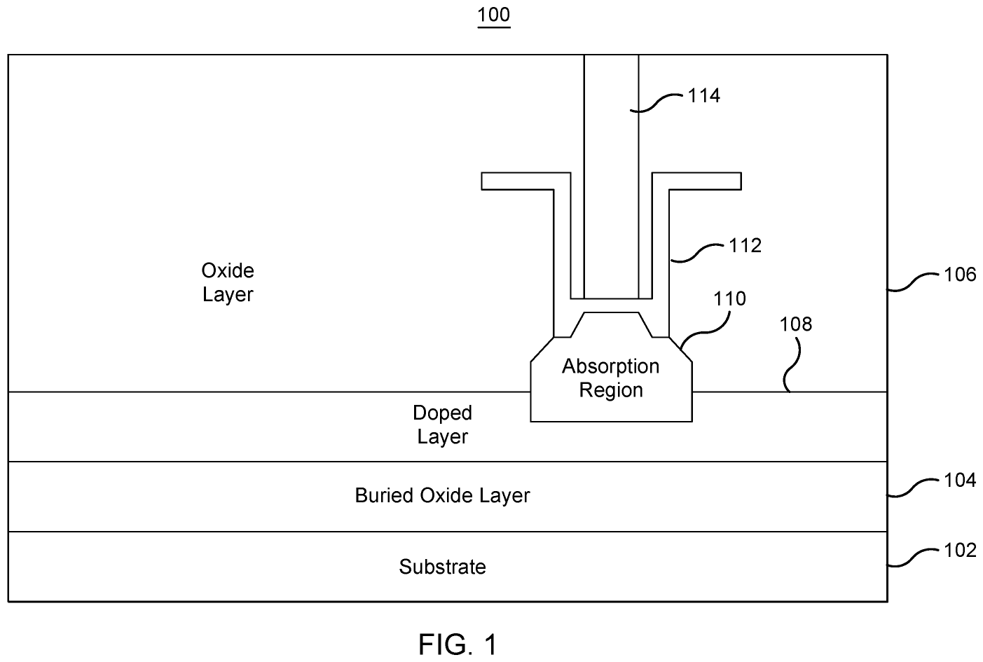

FIG. 1 illustrates an example photodiode 100. As seen in FIG. 1, the photodiode 100 includes a substrate 102, a buried oxide layer 104, an oxide layer 106, a doped layer 108, an absorption region 110, a cap 112, and a contact 114. Generally, the photodiode 100 converts an optical signal into an electrical signal. For example, an optical signal traveling through the absorption region 110 may separate electrical carriers (e.g., holes or electrons) in the absorption region 110. The separation of the carriers creates an electrical signal that travels through the contact 114 and out of the photodiode 100. In certain embodiments, the shape and structure of the absorption region 110 creates additional physical separation between the cap 112 and the doped layer 108 relative to existing photodiodes, which reduces the chances of junction breakdown and dark current spikes in certain embodiments.

The substrate 102 provides a structural foundation for the other components of the photodiode 100. For example, the other components of the photodiode 100 may be arranged on or above the substrate 102. The substrate 102 may be formed using any material. For example, the substrate 102 may be formed using silicon.

The buried oxide layer 104 may be formed on or in the substrate 102. The buried oxide layer 104 functions as an insulator layer that electrically separates the substrate 102 from other components of the photodiode 100. In some embodiments, the buried oxide layer 104 is formed by implanting or depositing oxygen on the surface of the substrate 102. This process may cause a layer in the substrate 102 to become the buried oxide layer 104.

The oxide layer 106 may be an insulator or dielectric layer formed or deposited on the buried oxide layer 104. Other components of the photodiode 100 may be formed in the oxide layer 106, and the oxide layer 106 may electrically isolate these components from each other. Any number of components may be formed in the oxide layer 106. For example, multiple waveguides may be formed in the oxide layer 106, and multiple absorption regions may be formed in the oxide layer 106.

The doped layer 108 may be a semiconductor formed in the oxide layer 106. In the example of FIG. 1, the doped layer 108 is formed on the buried oxide layer 104 and in the oxide layer 106. The doped layer 108 may be formed using any material. For example, the doped layer 108 may be a silicon doped layer. In some embodiments, the doped layer 108 is an n-doped silicon doped layer.

The absorption region 110 is formed on or in the doped layer 108. In some embodiments, the absorption region 110 is formed within a cavity defined by the doped layer 108. The absorption region 110 extends out of the cavity. The absorption region 110 may be formed using any material. For example, the absorption region 110 may be a germanium absorption region 110. Optical signals traveling through the absorption region 110 may separate electrical carriers in the absorption region 110. These electrical carriers may then travel towards the doped layer 108 or the cap 112, which creates an electric current. In this manner, the photodiode 100 converts an optical signal into an electrical signal.

The cap 112 is formed or positioned on the absorption region 110. The cap 112 may be formed using any material. For example, the cap 112 may be a silicon cap. Additionally, the cap 112 may be doped. In some embodiments, the cap 112 is a p-doped silicon cap. The doping of the cap 112 may be opposite the doping of the doped layer 108. For example, if the doped layer 108 is n-doped, then the cap 112 may be a p-doped cap 112. Alternatively, if the doped layer 108 is p-doped, then the cap 112 may be an n-doped cap 112.

Generally, one way to increase the speed of a photodiode is to reduce the size of the absorption region 110. For example, reducing the width or thickness of the absorption region 110 may increase the speed of the photodiode 100. In existing photodiodes, reducing the width or thickness of the absorption region may cause the cap 112 to be brought too close to the doped layer 108, which increases the risk of junction breakdown and dark current spikes. In the example of FIG. 1, the shape of the absorption region 110 creates additional physical separation between the cap 112 and the doped layer 108 relative to existing photodiodes. This additional physical separation may reduce the risk of junction breakdown and dark current spikes when the size of the absorption region 110 is reduced.

The contact 114 may be a metal contact formed on the cap 112. The contact 114 may conduct electrical signals created by the separation of electrical carriers in the absorption region 110. The contact 114 may carry the electrical signals out of the photodiode 100.

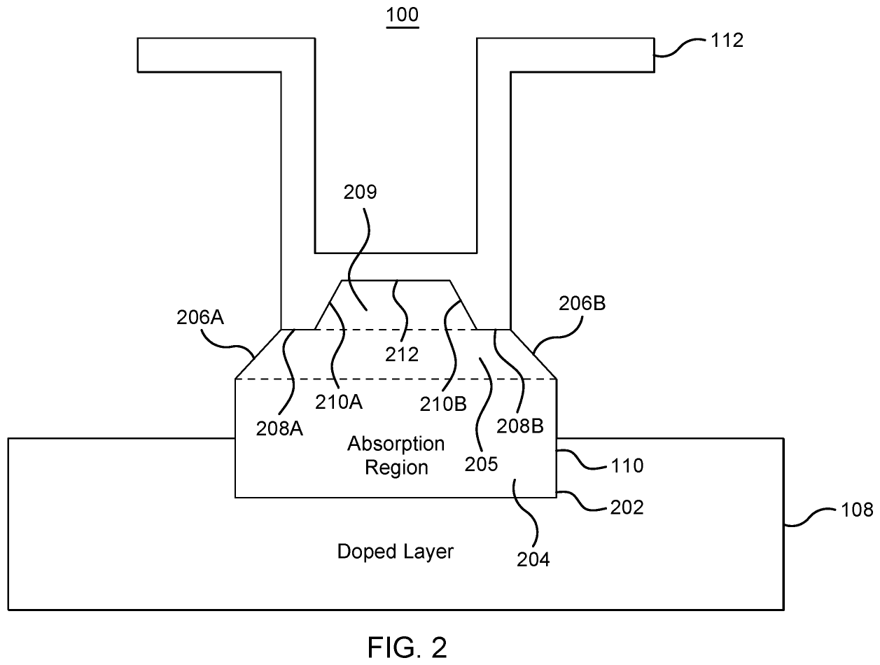

FIG. 2 illustrates an example portion of the photodiode 100 of FIG. 1. Specifically, FIG. 2 illustrates the doped layer 108, the absorption region 110, and the cap 112. As seen in FIG. 2, the absorption region 110 is positioned in a cavity 202 defined by the doped layer 108. The absorption region 110 extends out of the cavity 202. Additionally, the cap 112 is formed on the absorption region 110. Although other components of the photodiode 100 are not illustrated in FIG. 2, their absence does not suggest their removal from the photodiode 100.

The absorption region 110 includes a base region 204, a facet region 205, and a facet region 209. A portion of the base region 204 is positioned in the cavity 202 defined by the doped layer 108. A portion of the base region 204 extends out of the cavity 202. The base region 204 may be a rectangular region of the absorption region 110. The facet region 205 is positioned on or on top of the base region 204. The facet region 209 is positioned on or on top of the facet region 205. The base region 204 is wider than the facet region 205, and the facet region 205 is wider than the facet region 209. The base region 204, the facet region 205, and the facet region 209 are delineated using dashed lines in FIG. 2, but it is understood that the base region 204, the facet region 205, and the facet region 209 are three regions of one continuous structure, referred to as the absorption region 110.

The shapes of the facet region 205 and the facet region 209 create additional physical separation between the cap 112 and the doped layer 108. As seen in FIG. 2, the facet region 205 includes tapered surfaces 206A and 206B extending from the base region 204. Specifically, the tapered surfaces 206A and 206B extend vertically upwards and laterally towards the center of the absorption region 110, such that the tapered surfaces 206A and 206B extend from the base region 204 and towards each other. Additionally, the facet region 205 includes step regions 208A and 208B. The step region 208A extends laterally from the tapered surface 206A, and the step region 208B extends laterally from the tapered surface 206B. The step regions 208A and 208B extend laterally towards each other from the tapered surfaces 206A and 206B, respectively. Additionally, the step regions 208A and 208B may be parallel to the bottom of the base region 204.

The facet region 209 is positioned on or on top of the facet region 205. As seen in FIG. 2, the facet region 209 includes tapered surfaces 210A and 210B. The tapered surface 210A extends from the step region 208A, and the tapered surface 210B extends from the step region 208B. The tapered surfaces 210A and 210B may extend towards each other from the step regions 208A and 208B, respectively. The facet region 209 also includes a top surface 212. The top surface 212 may be a top surface of the absorption region 110. As seen in FIG. 2, the top surface 212 may be parallel to the step regions 208A and 208B and the bottom of the base region 204. The top surface 212 may be coupled to the tapered surfaces 210A and 210B.

The cap 112 is formed on the absorption region 110. As seen in FIG. 2, the cap 112 may be positioned on the step regions 208A and 208B. Additionally, the cap 112 may be formed on the facet region 209, such that the cap 112 is formed on the tapered surfaces 210A and 210B and on the top surface 212. The facet region 205 and the facet region 209 may create additional physical separation between the cap 112 and the doped layer 108. This physical separation may reduce the risk of junction breakdown and dark current spikes in certain embodiments.

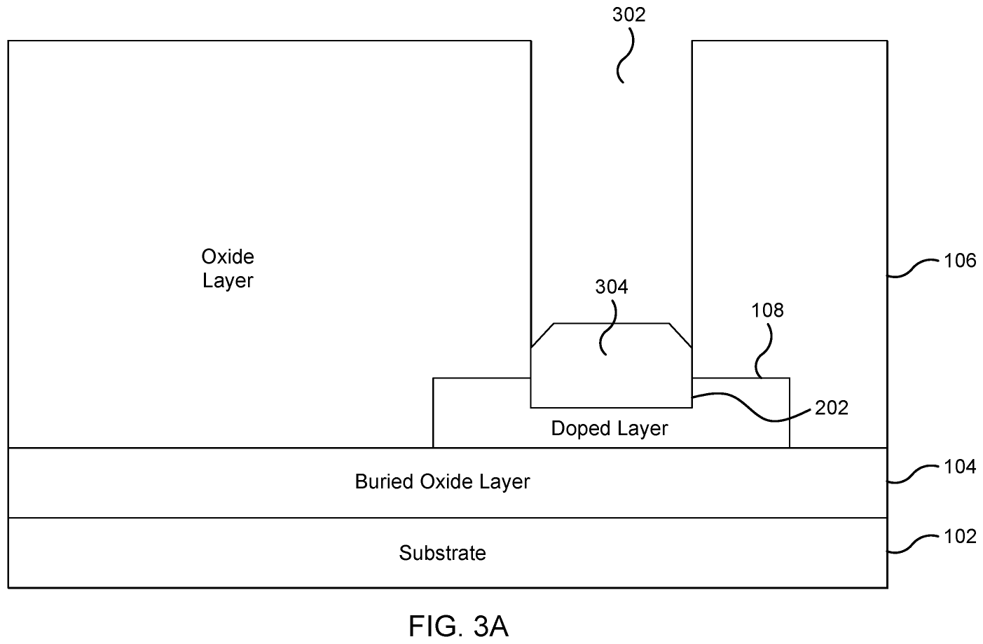

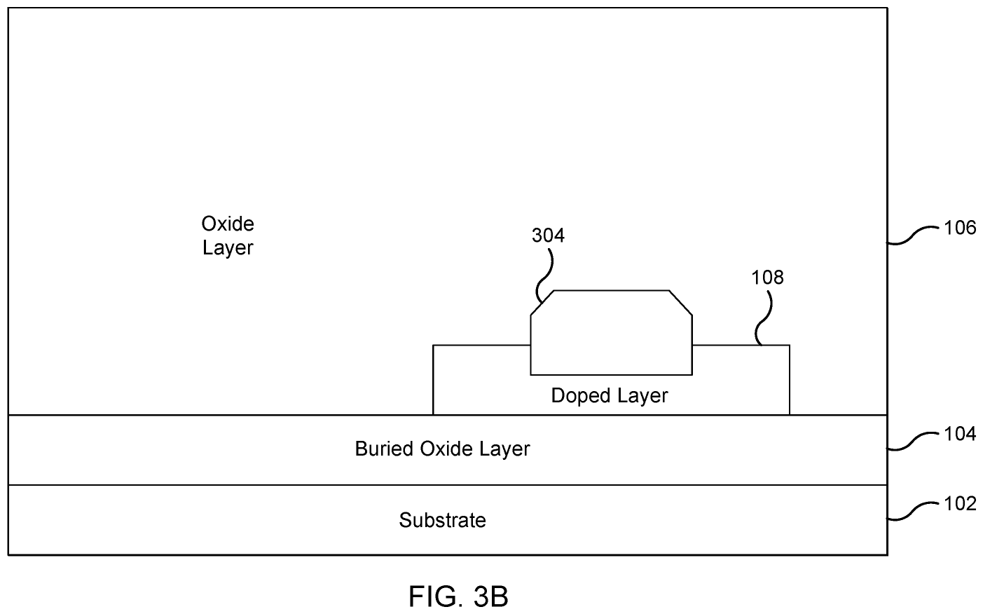

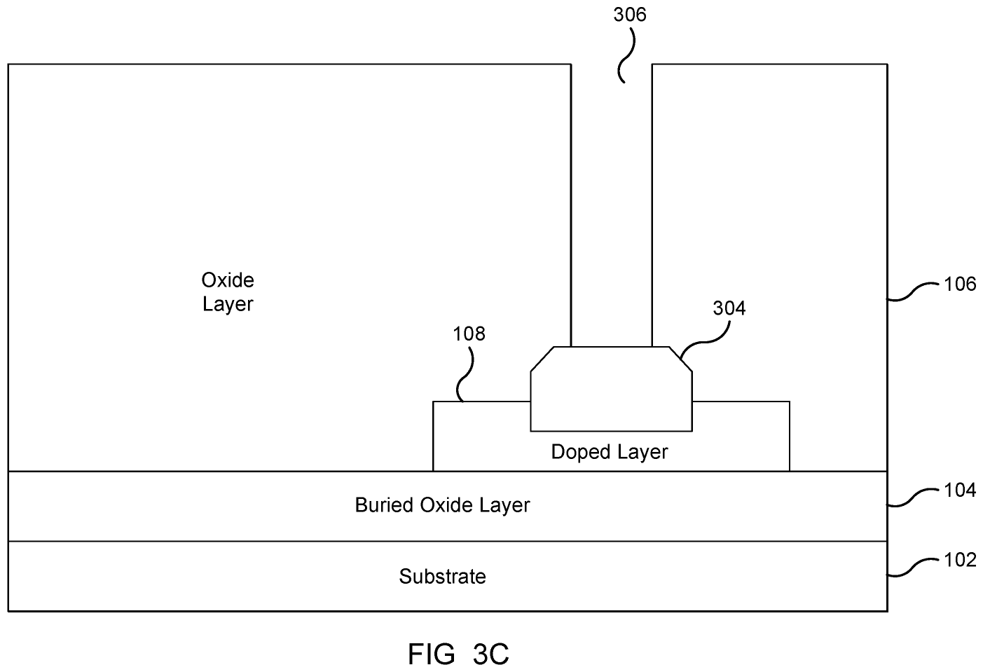

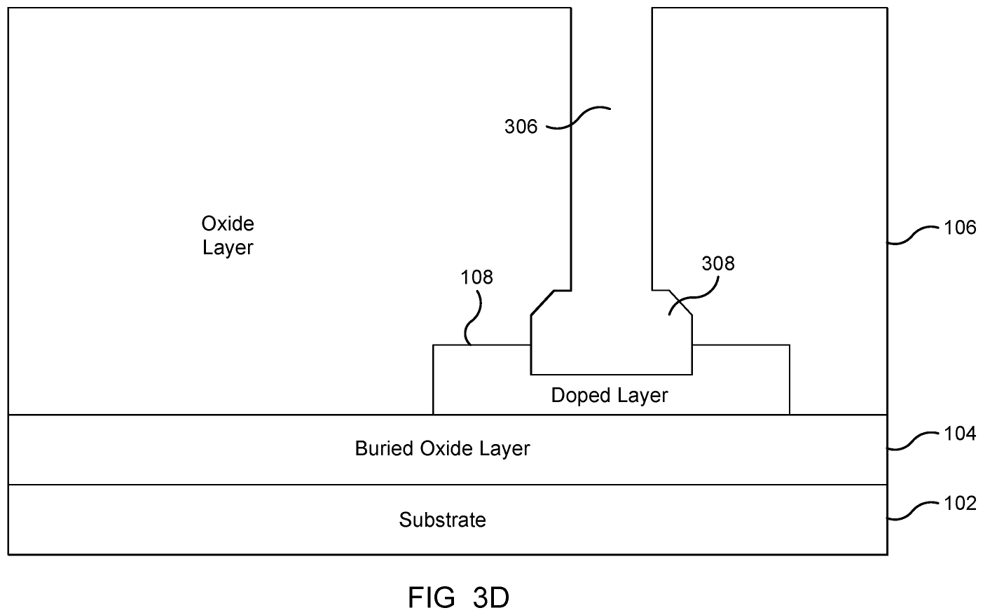

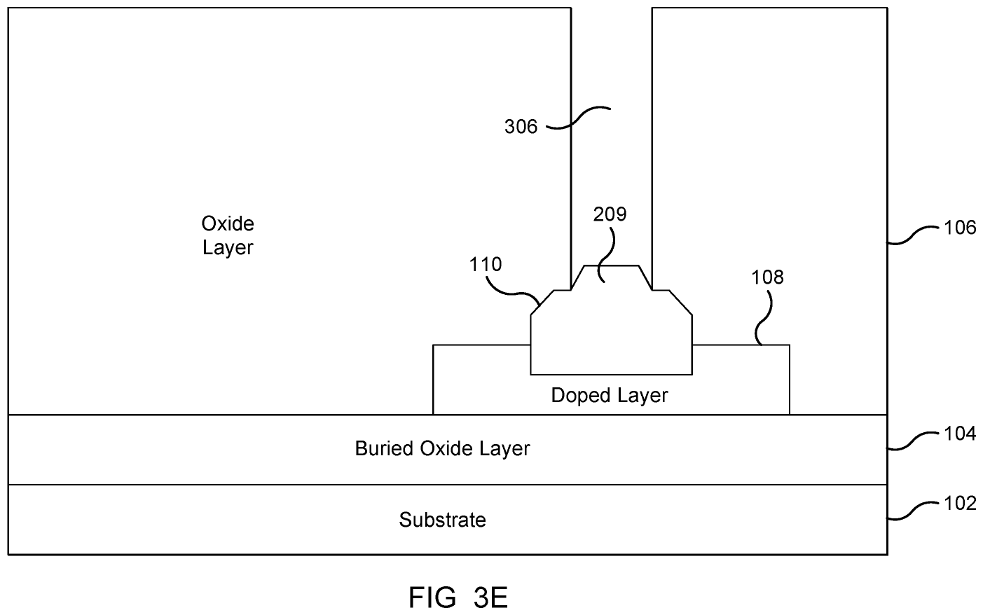

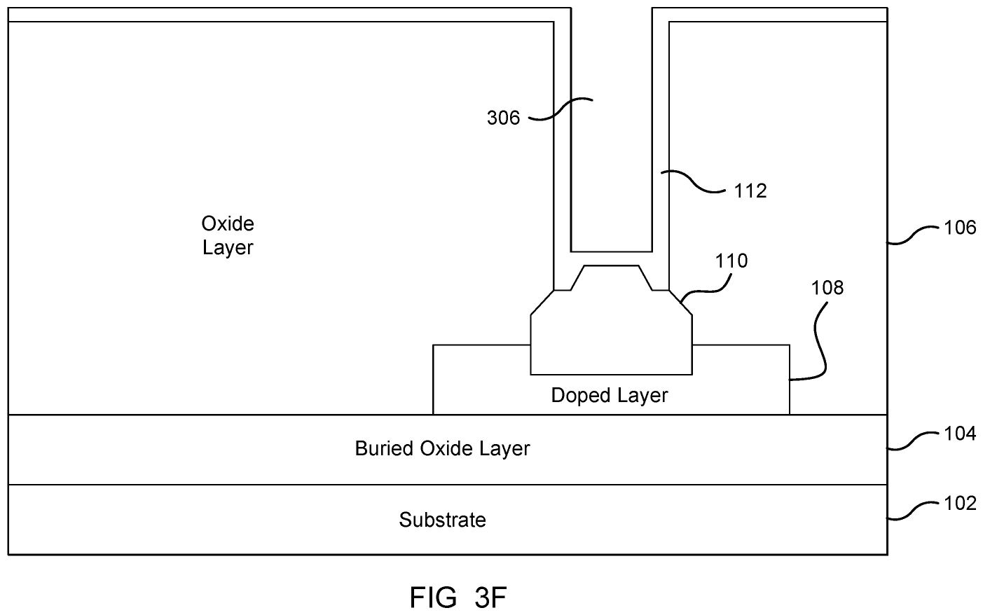

A sacrificial absorption region may be used to form the absorption region 110. FIGS. 3A through 3F illustrates steps of an example process for forming the photodiode 100 of FIG. 1. As seen in FIG. 3A, the process begins by etching a cavity 302 into the oxide layer 106 and the doped layer 108. Etching the cavity 302 may also etch the cavity 202 into the doped layer 108. As a result, the cavity 302 may have the same width as the cavity 202 in the doped layer 108. Additionally, etching the cavity 302 may expose the doped layer 108.

An absorption region 304 is then deposited or grown in the cavity 302. The absorption region 304 may include the same material used to form the absorption region 110. For example, the absorption region 304 may be a germanium absorption region. The absorption region 304, however, may be a sacrificial absorption region because the absorption region 304 may be removed during subsequent steps in the process. As seen in FIG. 3A, the absorption region 304 includes a base region and a facet region on the base region. The facet region includes tapered surfaces extending from the base region and a top surface connecting the tapered surfaces. The facet region forms at the top of the absorption region 304 as a result of the process for growing the absorption region 304. Specifically, the process for growing the absorption region 304 may cause the tapered surfaces to form at the top of the absorption region 304 from the side walls of the cavity 302 and towards the midline of the absorption region 304. Additionally, the facet region extends upwards into the cavity 302.

As seen in FIG. 3B, after the absorption region 304 is grown or deposited on the doped layer 108, the cavity 302 is filled in with oxide. As a result, the cavity 302 is filled in, and the absorption region 304 is closed off in the oxide layer 106. In some embodiments, the device may be planarized to smooth out or flatten the top of the device after the cavity 302 is filled in.

As seen in FIG. 3C, another cavity 306 is then etched into the oxide layer 106. The cavity 306 may extend down to the absorption region 304, and the cavity 306 may not be as wide as the original cavity 302. As a result, the cavity 306 may extend partially across the top surface of the absorption region 304 (as opposed to the cavity 302, which extended across the width of the absorption region 304.

The sacrificial absorption region 304 may then be removed (e.g., striped away) through the cavity 306. As seen in FIG. 3D, the absorption region 304 has been removed to form a cavity 308. The cavity 308 may be shaped similarly to the sacrificial absorption region 304. Additionally, the cavity 308 may connect to the cavity 306 and may extend into the doped layer 108. Another absorption region 110 may then be grown into the cavity 308.

As seen in FIG. 3E, the absorption region 110 is grown or deposited into the cavity 308 through the cavity 306. The absorption region 110 fills the cavity 308. Additionally, the facet region 209 of the absorption region 110 grows into the cavity 306. As a result of the width of the cavity 306 being smaller than the original cavity 302, the facet region 209 may not be as wide as the other portions of the absorption region 110. The facet region 209 extends upwards into the cavity 306, which may create additional vertical separation between the doped layer 108 and a cap 112 that is grown on the facet region 209.

Consistent with the growth of the absorption region 304 in FIG. 3A, the growth of the absorption region 110 causes the facet region 209 to grow up and into the cavity 306. Additionally, the process causes tapered surfaces to extend from the sidewalls of the cavity 306 and towards the midline of the absorption region 110. Because the width of the cavity 306 is not as wide as the cavity 302 in FIG. 3A, the width of the facet region 209 is not as wide as the other portions of the absorption region 110. The filling of the cavity 308 causes the shape of the absorption region 110 beneath the facet region 209 to be the same as the shape of the absorption region 304.

After the absorption region 110 is grown or deposited, the cap 112 is formed on the absorption region 110. A material such as silicon may be deposited across the exposed top surface of the device to form the cap 112. As seen in FIG. 3F, the material may be deposited across the top surface of the device and into the cavity 306. As a result, the material may be deposited onto a portion of the absorption region 110 that is exposed by the cavity 306. The material may also adhere to the sides of the cavity 306.

The cap 112 may be positioned on the facet region 209 of the absorption region 110. Because the facet region 209 extends upwards into the cavity 306, the facet region 209 may create additional physical separation between the cap 112 and the doped layer 108. As discussed previously, the doped layer 108 and the cap 112 may have opposite doping types. For example, the cap 112 may be p-doped and the doped layer 108 may be n-doped. As a result, when the cap 112 is too close to the doped layer 108, there is a risk of junction breakdown and dark spike currents. The additional physical separation created by the facet region 209 may reduce the risk of junction breakdown and dark spike currents.

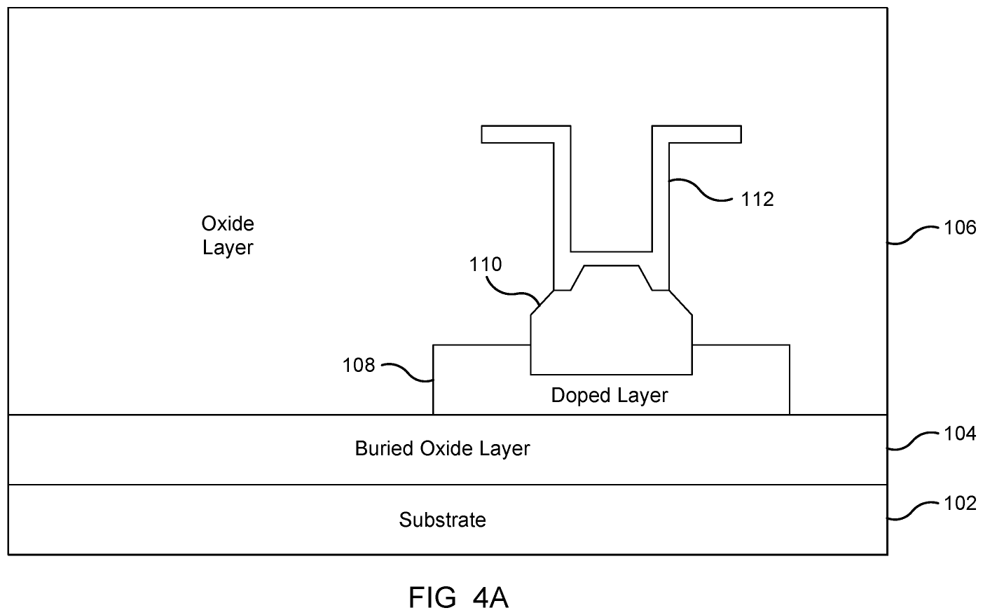

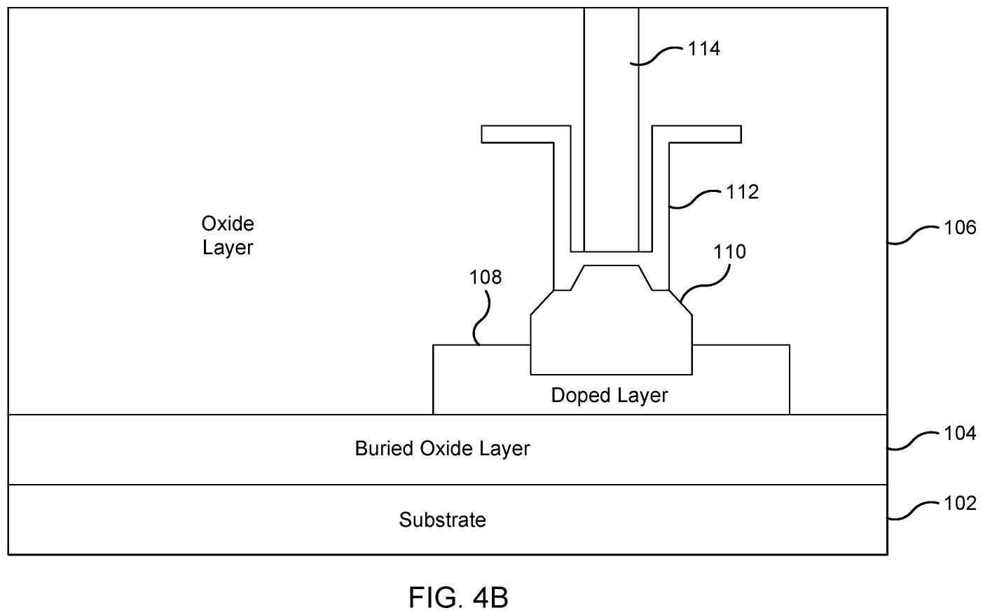

The material may then be processed in different ways to form the cap 112. FIGS. 4A and 4B illustrate steps of an example process for forming the cap 112 and the contact 114. As seen in FIG. 4A, after the material for the cap 112 has been deposited onto the device, some of the material at the top of the device may be etched away, and then additional oxide may be deposited onto the oxide layer 106. As a result, the cap 112 is shaped and sealed within the oxide layer 106. In some embodiments, the device may then be planarized to smooth out or flatten the top of the device. As seen in FIG. 4B, after the cap 112 is formed, the contact 114 may be formed into the oxide layer 106 such that the contact 114 extends down to the cap 112.

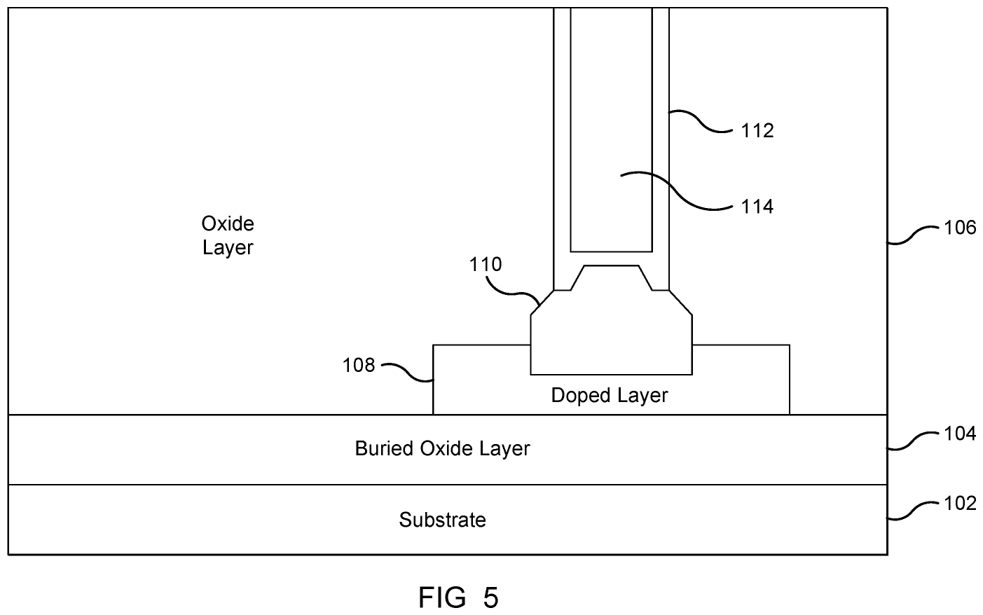

In an alternative process, after the material for the cap 112 has been deposited onto the device, the top of the device may be planarized to remove portions of the material for the cap 112 that extend horizontally across the top of the device. FIG. 5 illustrates a step of an example process for forming the cap 112 and the contact 114. As seen in FIG. 5, the top of the device was planarized to remove the material for the cap 112 on the top of the device. As a result, the cap 112 extends to the top of the device. Then, the metal contact 114 is deposited into the cavity 306 such that the contact 114 extends down to the cap 112. Thus, both the cap 112 and the contact 114 extend to the top of the device.

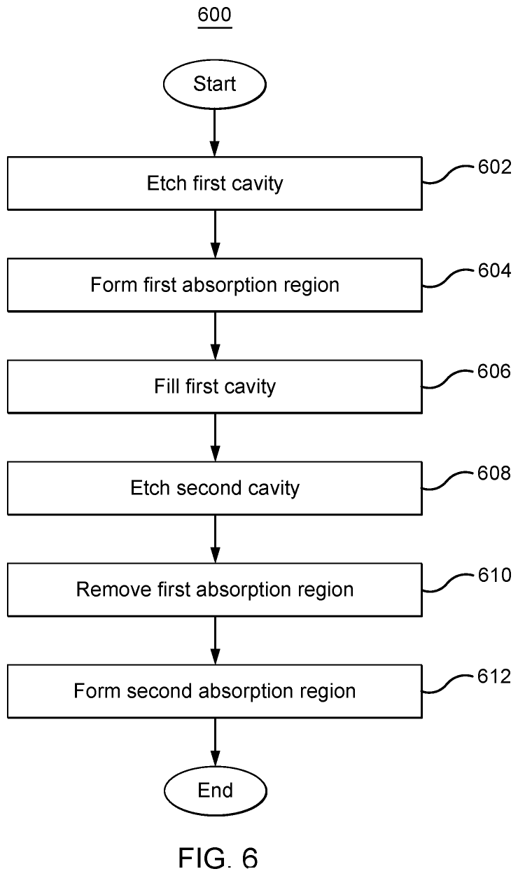

FIG. 6 is a flowchart of an example method 600 of forming the photodiode 100 of FIG. 1. In particular embodiments, a machine or circuit manufacturer may perform the method 600. By performing the method 600, the resulting photodiode 100 may include an absorption region that creates additional physical separation between the cap 112 and the doped layer 108, which reduces the risk of junction breakdown and dark current spikes.

In block 602, the machine etches a first cavity 302 into the oxide layer 106 and the doped layer 108. The cavity 302 may extend from the top of the device down into the doped layer 108. Part of the cavity 302 may form the cavity 202 in the doped layer 108. The doped layer 108 may be an n-doped silicon doped layer 108.

In block 604, the machine forms a first absorption region 304 in the cavity 302. The absorption region 304 may be positioned in the cavity 202 of the doped layer 108. In some embodiments, the absorption region 304 includes germanium. Due to the growth process, the absorption region 304 may include a facet region that grows up and into the cavity 302. The facet region may include tapered surfaces that extend from the sidewalls of the cavity 302 and towards the midline of the absorption region 304.

In block 606, the machine fills the first cavity 302. As a result, the absorption region 304 may be closed off in the oxide layer 106. In some embodiments, the machine may planarize the top surface of the oxide layer 106 to flatten or smooth out the top surface of the oxide layer 106.

In block 608, the machine etches a second cavity 306 into the oxide layer 106. The second cavity 306 may extend from the top of the device through the oxide layer 106 and to the absorption region 304. The first cavity 302 may be wider than the second cavity 306. As a result, the second cavity 306 may extend only partially across a top surface of the first absorption region 304.

In block 610, the machine removes the first absorption region 304. For example, the machine may etch or strip away the first absorption region 304 through the cavity 306. Removing the first absorption region 304 creates a cavity 308 that is connected to the cavity 306. The cavity 308 may be shaped like the first absorption region 304.

In block 612, the machine forms a second absorption region 110 through the cavity 306. The second absorption region 110 may fill the cavity 308 left by the first absorption region 304. Additionally, the second absorption region 110 may include a facet region 209 that grows into the second cavity 306. Because the second cavity 306 is not as wide as the first cavity 302 used to form the first absorption region 304, the facet region 209 may not be as wide as other portions of the absorption region 110. However, the facet region 209 may extend vertically higher than the other portions of the absorption region 110 into the cavity 306.

Consistent with the growth of the absorption region 304 in block 604, the growth of the absorption region 110 causes the facet region 209 to grow up and into the cavity 306. Additionally, the process causes tapered surfaces 206A and 206B to extend from the sidewalls of the cavity 306 and towards the midline of the absorption region 110. Because the width of the cavity 306 is not as wide as the cavity 302, the width of the facet region 209 is not as wide as the other portions of the absorption region 110.

As a result of the shape and structure of the second absorption region 110, the cap 112 that is subsequently formed onto the absorption region 110 may be more vertically separated from the doped layer 108. As discussed previously, the doped layer 108 and the cap 112 may have opposite doping types. For example, the cap 112 may be p-doped and the doped layer 108 may be n-doped. When an optical signal travels through the absorption region 110, the optical signal may separate electrical carriers in the absorption region 110. The electrical carriers may then travel to the doped layer 108 or the cap 112 to create an electrical signal. When the cap 112 is too close to the doped layer 108, there is a risk of junction breakdown and dark spike currents. The additional physical separation created by the facet region 209 may reduce the risk of junction breakdown and dark spike currents in the photodiode 100.

In summary, the photodiode 100 has an absorption region 110 that creates increased physical separation between oppositely doped regions. The absorption region 110 has a base region 204 that is positioned within a cavity 202 of a doped layer 108. A first facet region 205 is positioned on the base region 204, and a second facet region 209 is positioned on the first facet region 205. A silicon cap 112 (e.g., p-doped silicon cap 112) is positioned on the first facet region 205 and the second facet region 209.

In certain embodiments, as a result of the shape of the absorption region 110, the absorption region 110 creates additional physical separation between the silicon cap 112 and a doped layer 108 (e.g., an n-doped layer 108) in both lateral and vertical directions relative to existing photodiodes. Thus, the photodiode 100 reduces the chances of junction breakdown and dark current spikes.

In the current disclosure, reference is made to various embodiments. However, the scope of the present disclosure is not limited to specific described embodiments. Instead, any combination of the described features and elements, whether related to different embodiments or not, is contemplated to implement and practice contemplated embodiments. Additionally, when elements of the embodiments are described in the form of “at least one of A and B,” or “at least one of A or B,” it will be understood that embodiments including element A exclusively, including element B exclusively, and including element A and B are each contemplated. Furthermore, although some embodiments disclosed herein may achieve advantages over other possible solutions or over the prior art, whether or not a particular advantage is achieved by a given embodiment is not limiting of the scope of the present disclosure. Thus, the aspects, features, embodiments and advantages disclosed herein are merely illustrative and are not considered elements or limitations of the appended claims except where explicitly recited in a claim(s). Likewise, reference to “the invention” shall not be construed as a generalization of any inventive subject matter disclosed herein and shall not be considered to be an element or limitation of the appended claims except where explicitly recited in a claim(s).

In view of the foregoing, the scope of the present disclosure is determined by the claims that follow.

We claim:

1. A photodiode comprising:
a doped layer; and
an absorption region positioned on the doped layer, wherein the absorption region comprises:
a base region contacting the doped layer;
a first facet region positioned on the base region, wherein the first facet region comprises (i) a first tapered surface and a second tapered surface extending from the base region and (ii) a first step region and a second step region extending laterally from the first tapered surface and the second tapered surface respectively; and
a second facet region positioned on the first facet region, wherein the second facet region comprises a third tapered surface extending from the first step region and a fourth tapered surface extending from the second step region.

2. The photodiode of claim 1, wherein the doped layer defines a cavity and wherein the base region is positioned within the cavity.

3. The photodiode of claim 1, further comprising a silicon cap positioned on the first step region, the second step region, and the second facet region.

4. The photodiode of claim 3, further comprising a metal contact positioned on the silicon cap.

5. The photodiode of claim 4, wherein the metal contact and the silicon cap extend to a top surface of the photodiode.

6. The photodiode of claim 3, wherein the doped layer has a first doping and the silicon cap has a second doping opposite the first doping.

7. The photodiode of claim 1, wherein the base region is wider than the first facet region, and wherein the first facet region is wider than the second facet region.

8. The photodiode of claim 1, wherein the first step region extends laterally from the first tapered surface, and wherein the second step region extends laterally from the second tapered surface towards the first step region.

9. A method of forming a photodiode, the method comprising:
etching a first cavity in an oxide layer to expose a doped layer;
forming a first absorption region on the doped layer;
filling the first cavity in the oxide layer;
etching a second cavity in the oxide layer to expose the first absorption region;
removing the first absorption region to produce a third cavity; and
forming a second absorption region in the third cavity.

10. The method of claim 9, wherein the second absorption region comprises:
a base region contacting the doped layer;
a first facet region positioned on the base region, wherein the first facet region comprises (i) a first tapered surface and a second tapered surface extending from the base region and (ii) a first step region and a second step region extending laterally from the first tapered surface and the second tapered surface respectively; and
a second facet region positioned on the first facet region, wherein the second facet region comprises a third tapered surface extending from the first step region and a fourth tapered surface extending from the second step region.

11. The method of claim 10, further comprising forming a silicon cap on the first step region, the second step region, and the second facet region.

12. The method of claim 11, further comprising forming a metal contact on the silicon cap.

13. The method of claim 11, wherein the doped layer has a first doping and the silicon cap has a second doping opposite the first doping.

14. The method of claim 10, wherein the base region is wider than the first facet region, and wherein the first facet region is wider than the second facet region.

15. The method of claim 9, wherein the third cavity extends into the doped layer.

16. The method of claim 9, wherein the first cavity is wider than the second cavity.

17. An absorption region of a photodiode, the absorption region comprising:
a base region;
a first facet region positioned on the base region, wherein the first facet region comprises (i) a first tapered surface and a second tapered surface extending from the base region and (ii) a first step region and a second step region extending laterally from the first tapered surface and the second tapered surface respectively; and
a second facet region positioned on the first facet region, wherein the second facet region comprises a third tapered surface extending from the first step region and a fourth tapered surface extending from the second step region.

18. The absorption region of claim 17, further comprising a silicon cap positioned on the first step region, the second step region, and the second facet region.

19. The absorption region of claim 18, further comprising a metal contact positioned on the silicon cap.

20. The absorption region of claim 19, wherein the metal contact and the silicon cap extend to a top surface of the photodiode.
